(19) United States
(12) Patent Application Publication
(10) Pub. No.: US 2024/0010898 A1
(43) Pub. Date: Jan. 11, 2024

(54) THERMALLY CONDUCTIVE SHEET AND METHOD FOR MANUFACTURING THERMALLY CONDUCTIVE SHEET

(71) Applicant: DEXERIALS CORPORATION, Shimotsuke-shi, Tochigi (JP)

(72) Inventors: Yuma SATO, Shimotsuke-shi, Tochigi (JP); Keisuke ARAMAKI, Shimotsuke-shi, Tochigi (JP); Yusuke KUBO, Shimotsuke-shi, Tochigi (JP)

(73) Assignee: DEXERIALS CORPORATION, Shimotsuke-shi, Tochigi (JP)

(21) Appl. No.: 18/021,595

(22) PCT Filed: Aug. 3, 2021
(86) PCT No.: PCT/JP2021/028783

§ 371 Date: Feb. 16, 2023

(30) Foreign Application Priority Data
Aug. 25, 2020 (JP) 2020-141833

(51) Int. Cl. C09K 5/14; C08K 7/00; C08L 83/04

(52) U.S. Cl. CPC C09K 5/14; C08K 7/00; C08L 83/04; C08K 2201/001

(57) ABSTRACT

Provided is a thermally conductive sheet which is highly flexible and of which the thermal resistance value has small load dependency. A thermally conductive sheet 1 contains a curable resin composition 2, a flaky thermally conductive filler 3, and a non-flaky thermally conductive filler 4, wherein the amount of change between the thermal resistance value at load of 1 kgf/cm² and the thermal resistance value at load in a range greater than 1 kgf/cm² and not greater than 3 kgf/cm² is not greater than 0.4° C.·cm²/W, and the amount of change between the compression rate at load of 3 kgf/cm² and the compression rate at load of 1 kgf/cm² is not less than 20%.

### TECHNICAL FIELD

The present technology relates to a thermally conductive sheet and a method for manufacturing a thermally conductive sheet. The present application claims priority based on Japanese Patent Application No. 2020-141833 filed in Japan on Aug. 25, 2020, and the contents of this application are hereby incorporated by reference.

### BACKGROUND TECHNOLOGY

Semiconductor elements are becoming increasingly dense and increasingly commonly implemented in conjunction with the increasing performance of electronic devices. Accordingly, it is important that the heat generated from electronic equipment configuring such electronic devices be efficiently dissipated. For example, in order for a semiconductor device to efficiently dissipate heat, electronic equipment is attached to a heat sink such as a heat dissipating fan or a heat exchange plate via a thermally conductive sheet. For example, silicone resins containing (having undergone dispersion of) a filling agent such as an inorganic filler are widely used for thermally conductive sheets. A heat dissipating member such as these thermally conductive sheets is required for further improvement of thermal conductivity. For example, with high thermal conductivity in thermally conductive sheets as an aim, increased filling ratios of inorganic fillers included in a matrix such as a binding resin are being studied. However, because a high ratio of inorganic filler can lead to impaired flexibility of the thermally conductive sheets, crumbling into powder, and the like, there is a limit to the filling ratio of inorganic fillers.

Examples of inorganic fillers include: alumina, aluminum nitride, aluminum hydroxide, and the like. Furthermore, flake-like particles of boron nitride, graphite, and the like, and carbon fibers and the like may be filled in a matrix for the purpose of high thermal conductivity. This is because flake-like particles and the like have anisotropic thermal conductivity. For example, some carbon fibers are known to possess thermal conductivity of approximately 600 to 1,200 W/m·K in a direction of the fibers. Moreover, some boron nitrides are known to possess thermal conductivity of approximately 110 W/m·K in a surface direction and to possess thermal conductivity of approximately 2 W/m·K in a direction perpendicular to the surface direction. Thus, a surface direction of a carbon fiber or flake-like particle can be made the same as a thickness direction of a sheet, being the direction of heat transmittance. That is, by aligning the carbon fibers or flake-like particles in the thickness direction of the sheet, thermal conductivity can be expected to improve dramatically.

Additionally, when a cured product, which is formed and then cured, cannot be sliced to a uniform thickness when slicing, there are problems with uneven portions forming more readily on the sheet surface, air getting trapped in the uneven portions, and superior thermal conductivity going unutilized. In order to resolve these problems, for example, Patent Document 1 proposes a thermally conductive rubber sheet formed by punching out and slicing using blades aligned at equal intervals in a direction perpendicular to the longitudinal direction of the sheet. Additionally, Patent Document 2 proposes obtaining a thermally conductive sheet of a prescribed thickness by slicing a laminate body laminated by repeatedly coating and curing using a cutting device having circular rotating blade. Furthermore, Patent Document 3 proposes using a metal saw to cut a laminate body in which two or more graphite layers containing anisotropic graphite particles are laminated such that an expanded graphite sheet is aligned at 0° to the thickness direction of the obtained sheet (90° angle to the laminated surface). However, problems with these proposed cutting methods include increased surface roughness on cut surfaces, which leads to increased thermal resistance at an interface and decreased thermal conductivity in the thickness direction.

In recent years, there has been demand for a thermally conductive sheet used by being interposed between various heat generating bodies (for example, various devices such as LSIs, CPUs (Central Processing Units), transistors, LEDs, and the like) and a heat dissipating body. It is desired that thermally conductive sheets be compressible and soft so that they closely adhere by filling in unevenness between the various heat generating bodies and the heat dissipating body.

Generally, thermally conductive sheets are filled with a large amount of a thermally conductive inorganic filler in order to increase the thermal conductivity of the sheets (for example, see Patent Documents 4 and 5). However, when filled with a large amount of inorganic filler, sheets tend to become harder and more brittle. Furthermore, for example, when silicone-based thermally conductive sheets filled with a large amount of an inorganic filler are placed in a high temperature environment for a long period time, events in which the thermally conductive sheets harden and events in which thermally conductive sheets become thicker are observed, and there is a risk that thermal resistance of the thermal sheets will increase when a load is applied.

### CITATION LIST

### Patent Documents

Patent Document 1: Japanese Unexamined Patent Application Publication No. 2010-56299

Patent Document 2: Japanese Unexamined Patent Application Publication No. 2010-50240

Patent Document 3: Japanese Unexamined Patent Application Publication No. 2009-55021

Patent Document 4: Japanese Unexamined Patent Application Publication No. 2007-277406

Patent Document 5: Japanese Unexamined Patent Application Publication No. 2007-277405

### SUMMARY OF INVENTION

### Problem to be Solved by Invention

The present technology is proposed in light of such conventional circumstances, proposing a thermally conductive sheet having superior flexibility and low load-dependency on thermal resistance.

### Means to Solve the Problem

The thermally conductive sheet according to the present technology has a curable resin composition and contains a flake-like thermally conductive filler and a non-flake-like thermally conductive filler, wherein a difference between a thermal resistance value at a load of 1 kgf/cm² and a thermal resistance value at a load in the range of 1 kgf/cm² to 3 kgf/cm² is 0.4° C.·cm²/W or less, and a difference between a compression ratio at a load of 3 kgf/cm² and a compression ratio at a load of 1 kgf/cm² is 20% or more.

The method for manufacturing the thermally conductive sheet according to the present technology has a step A for preparing the resin composition for forming the thermally conductive sheet by dispersing the flake-like thermally conductive filler and the non-flake-like thermally conductive filler in the curable resin composition, a step B for forming a molded body block from the resin composition for forming the thermally conductive sheet, a step C for obtaining the thermally conductive sheet by slicing the molded body block into sheets, wherein the difference between a thermal resistance value at a load of 1 kgf/cm² and a thermal resistance value at a load in the range of 1 kgf/cm² to 3 kgf/cm² is 0.4° C.·cm²/W or less, and the difference between a compression ratio at a load of 3 kgf/cm² and a compression ratio at a load of 1 kgf/cm² is 20% or more.

### Effect of the Invention

According to the present technology, a thermally conductive sheet can be provided that has superior flexibility and low load-dependency on thermal resistance.

### BRIEF DESCRIPTION OF THE DRAWINGS

FIG. 1 is a cross-sectional view illustrating an example of the thermally conductive sheet according to the present technology.

FIG. 2 is a perspective view schematically illustrating a flake-like boron nitride having a hexagonal crystal shape, which is an example of a flake-like thermally conductive filler.

FIG. 3 is a cross-sectional view illustrating an example of a semiconductor device to which thermally conductive sheet according to the present technology is applied.

FIG. 4 is a graph illustrating a relationship between thicknesses and compression ratios of the thermally conductive sheet.

FIG. 5 is a graph illustrating a relationship between loads and thermal resistance values for the thermally conductive sheet in Example 1.

FIG. 6 is a graph illustrating a relationship between loads and thermal resistance values for the thermally conductive sheet in Example 2.

FIG. 7 is a graph illustrating a relationship between loads and thermal resistance values for the thermally conductive sheet in Example 3.

FIG. 8 is a graph illustrating a relationship between loads and thermal resistance values for the thermally conductive sheet in Comparative Example 1.

FIG. 9 is a graph illustrating a relationship between loads and compression ratios for the thermally conductive sheet in Example 1.

FIG. 10 is a graph illustrating a relationship between loads and compression ratios for the thermally conductive sheet in Example 2.

FIG. 11 is a graph illustrating a relationship between loads and compression ratios for the thermally conductive sheet in Example 3.

FIG. 12 is a graph illustrating a relationship between loads and compression ratios for the thermally conductive sheet in Comparative Example 1.

FIG. 13 is a graph illustrating a relationship between thicknesses and effective thermal conductivities of the thermally conductive sheet.

FIG. 14 is a graph illustrating a relationship between compression ratios and effective thermal conductivities for the thermally conductive sheet in Example 1.

FIG. 15 is a graph illustrating a relationship between compression ratios and effective thermal conductivities for the thermally conductive sheet in Example 2.

FIG. 16 is a graph illustrating a relationship between compression ratios and effective thermal conductivities for the thermally conductive sheet in Example 3.

FIG. 17 is a graph illustrating a relationship between compression ratios and effective thermal conductivities for the thermally conductive sheet in Comparative Example 1.

### DESCRIPTION OF THE EMBODIMENTS

In the present Specification, when an overall particle diameter distribution of a thermally conductive filler is set to 100% and a cumulative curve of the particle diameter values is obtained from the smaller particle diameter side of the particle distribution, an average particle diameter (D50) of the thermally conductive filler refers to the particle diameter when the cumulative value is 50%. Note that the particle distribution (particle diameter distribution) in the present specification is obtained on a volumetric basis. A method in which a laser diffraction type particle size distribution measuring apparatus is used can be given as an example of a method for measuring particle distribution.

<Thermally Conductive Sheet>

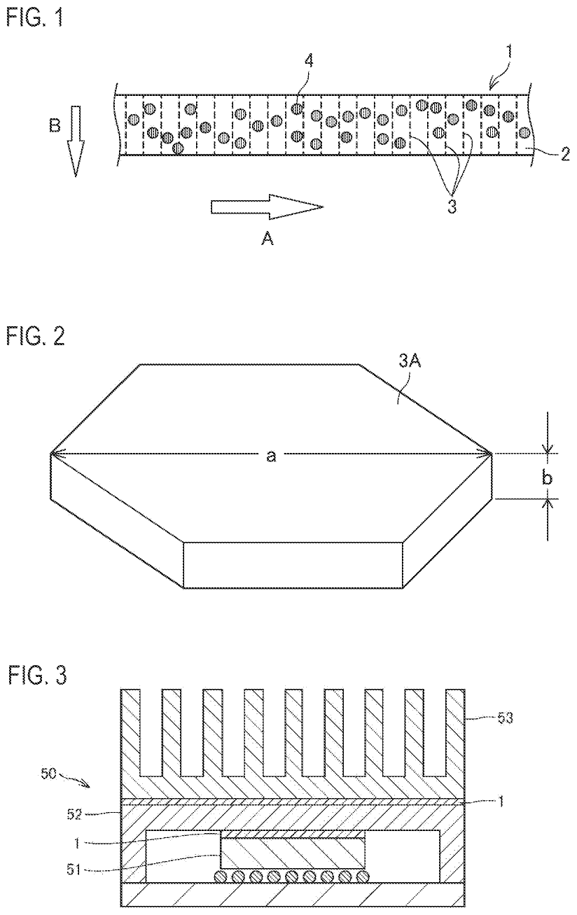

FIG. 1 is a cross-sectional drawing illustrating an example of a thermally conductive sheet 1 according to the present technology. The thermally conductive sheet 1 contains a curable resin composition 2, a flake-like thermally conductive filler 3, and a non-flake-like thermally conductive filler 4. In the thermally conductive sheet 1, it is preferable that the flake-like thermally conductive filler 3 and the non-flake-like thermally conductive filler 4 are dispersed in the curable resin composition 2.

In the thermally conductive sheet 1, a difference between a compression ratio at a load of 3 kgf/cm² and a compression ratio at a load of 1 kgf/cm² is 20% or more. That is, the thermally conductive sheet 1 is highly flexible. Moreover, in the thermally conductive sheet 1, a difference between a thermal resistance value at a load of 1 kgf/cm² and a thermal resistance value at a load in the range of 1 kgf/cm² to 3 kgf/cm² is 0.4° C.·cm²/W or less. That is, the thermally conductive sheet 1 has low load-dependency on thermal resistance. Thus, the thermally conductive sheet 1 according to the present technology can have superior flexibility and low load-dependency on thermal resistance. Note that a lower limit of the difference between the thermal resistance value at a load of 1 kgf/cm² and the thermal resistance value at a load in the range of 1 kgf/cm² to 3 kgf/cm² is not particularly limited and may be, for example, 0.1° C.·cm²/W or more.

Furthermore, in addition to having superior flexibility and low load-dependency on thermal resistance, it is preferable that the thermally conductive sheet 1 have a peak value (maximum value) of conductivity in a low load region. In conventional thermally conductive sheets, while effective thermal conductivity increases as a load increases, thermal resistance decreases as the load increases. Thus, there is a risk that a thermally conductive sheet that exhibits a thermal property at a region having a certain level of a load (high load region) will damage an IC, which have been miniaturized in recent years.

Therefore, it is preferable that the thermally conductive sheet 1 according to the present technology has a peak value of effective thermal conductivity of 7 W/m·K or more in the range in which the compression ratio is 5 to 35%, and has a peak value of effective thermal conductivity of 7 W/m·K or more in the range in which the compression ratio is 15 to 25%. The range in which the compression ratio of the thermally conductive sheet 1 is 5 to 35% means a state where a low load is applied to the thermally conductive sheet 1. For example, it is preferable that the thermally conductive sheet 1 has a peak value of effective thermal conductivity of 7 W/m·K or more in the range in which a load is 1 kgf/cm² to 3 kgf/cm². As an example, it preferable that the thermally conductive sheet 1 may has a peak value of effective thermal conductivity of 7 W/m·K or more at a load of 1 kgf/cm², and the peak value of effective thermal conductivity may be 7.5 W/m·K or more, 8 W/m·K or more, 8.5 W/m·K or more, 9 W/m·K or more, and 10 W/m·K or more.

A configuration example of the thermally conductive sheet 1 according to the present technology is described below.

<Curable Resin Composition>

The curable resin composition 2 is for retaining the flake-like thermally conductive filler 3 and the non-flake-like thermally conductive filler 4 inside of the thermally conductive sheet 1. The curable resin composition 2 is selected according to mechanical strength, heat resistance, electrical properties, or another characteristic required by the thermally conductive sheet 1. The curable resin composition 2 can be selected from among a thermoplastic resin, a thermoplastic elastomer, and a thermosetting resin.

Examples of the thermoplastic resin include: polyethylene, polypropylene, an ethylene-propylene copolymer or another ethylene-α olefin copolymer, polymethylpentene, polyvinyl chloride, polyvinylidene chloride, polyvinyl acetate, an ethylene-vinyl acetate copolymer, polyvinyl alcohol, polyvinyl acetal, fluoropolymer such as polyvinylidene fluoride and polytetrafluoroethylene, polyethylene terephthalate, polybutylene terephthalate, polyethylene naphthalate, polystyrene, polyacrylonitrile, a styrene-acrylonitrile copolymer, an acrylonitrile-butadiene-styrene copolymer (ABS) resin, a polyphenylene ether copolymer (PPE) resin, modified PPE resin, aliphatic polyamide, aromatic polyamide, polyimide, polyamide-imide, polymethacrylic acid methyl ester or another polymethacrylate ester, polycarbonate, polyphenylene sulfide, polysulfone, polyether sulfone, polyether nitrile, polyether ketone, polyketone, a liquid crystal polymer, silicone resin, ionomer, and the like.

Examples of the thermoplastic elastomer include: a styrene butadiene block copolymer or a hydrogenated product thereof, a styrene isoprene block copolymer or a hydrogenated product thereof, a styrene thermoplastic elastomer, olefin thermoplastic elastomer, vinyl chloride thermoplastic elastomer, polyester thermoplastic elastomer, polyurethane thermoplastic elastomer, polyamide thermoplastic elastomer, and the like.

Examples of the thermosetting resin include: crosslinked rubber, epoxy resin, phenol resin, polyimide resin, unsaturated polyester resin, diallyl phthalate resin, and the like. Specific examples of the crosslinked rubber include: natural rubber, acrylic rubber, butadiene rubber, isoprene rubber, a styrene-butadiene copolymer rubber, nitrile rubber, hydrogenated nitrile rubber, chloroprene rubber, ethylene-propylene copolymer rubber, chlorinated polyethylene rubber, chlorosulfonated polyethylene rubber, butyl rubber, halogenated butyl rubber, fluororubber, urethane rubber, and silicone rubber.

For the curable resin composition 2, for example, a silicone resin is preferable in terms of ability to closely adhere to a heat-generating surface of electronic equipment and a heat sink surface. For the silicone resin, for example, a silicon resin formed by subjecting two liquids to an addition reaction may be used, being composed of primary agents—containing a primary silicone component having an alkenyl group and a curing catalyst—and a curing agent having a hydrosilyl group (Si—H group). For the silicone having an alkenyl group, for example, a polyorganosiloxane having a vinyl group may be used. The curing catalyst is a catalyst for accelerating an addition reaction of the alkenyl group in the silicone having an alkenyl group and the hydrosilyl group in the curing agent having a hydrosilyl group. A catalyst well-known as a catalyst used for a hydrosilylation reaction can be given as an example of the curing catalyst and, for example, a platinum group curing catalyst, that is, a platinum group metal element such as platinum, rhodium, and palladium, or platinum chloride or the like can be used. For the curing agent having hydrosilyl group, for example, a polyorganosiloxane having a hydrosilyl group may be used. One type of the curable resin composition 2 may be used alone or two or more types may be combined.

When a liquid silicon resin formed by subjecting two liquids—a silicone primary agent and a curing agent—to an addition reaction is used as the curable resin composition 2, a compression ratio of the thermally conductive sheet 1 can be further increased by making a mass ratio of the silicone primary agent to the curing agent (silicone primary agent:curing agent) 5:5 to 7:3.

Content of the curable resin composition 2 in the thermally conductive sheet 1 is not particularly limited and may be appropriately selected according to the purpose. For example, a lower limit of content of the curable resin composition 2 in the thermally conductive sheet 1 can be 20 percent by volume or more, and may be 25 percent by volume or more or 30 percent by volume or more. Additionally, an upper limit of content of the curable resin composition 2 in the thermally conductive sheet 1 can be 70 percent by volume or less, and may be 60 percent by volume or less, 50 percent by volume or less, 40 percent by volume or less, or 37 percent by volume or less. From the perspective of flexibility or load-dependency on a thermal resistance value of the thermally conductive sheet 1, it is preferable that content of the curable resin composition 2 in the thermally conductive sheet 1 be set to 32 to 40 percent by volume. Moreover, from the perspectives of flexibility, load-dependency on a thermal resistance value, and thermal conductivity at a low load region of the thermally conductive sheet 1, it is preferable that content of the curable resin composition 2 in the thermally conductive sheet 1 be set to 33 to 37 percent by volume. Also, from the perspective of formability of the thermally conductive sheet 1, it is preferable that content of the curable resin composition 2 in the thermally conductive sheet 1 be set to 29 to 40 percent by volume.

<Flake-Like Thermally Conductive Filler>

The flake-like thermally conductive filler 3 has a high aspect ratio and isotropic effective thermal conductivity in a surface direction. The flake-like thermally conductive filler 3 is not particularly limited as long as it is flake-like, but is preferably a material that can ensure insulating properties of the thermally conductive sheet 1. For example, boron nitride (BN), mica, alumina, aluminum nitride, silicon carbide, silica, zinc oxide, molybdenum disulfide, and the like can be used for the flake-like thermally conductive filler 3.

FIG. 2 is a perspective view schematically illustrating a flake-like boron nitride 3A having a hexagonal crystal shape which is an example of the flake-like thermally conductive filler 3. From the perspective of effective thermal conductivity of the thermally conductive sheet 1, it is preferable that the flake-like boron nitride 3A having a hexagonal crystal shape, such as illustrated in FIG. 2, be used for the flake-like thermally conductive filler 3. One type of the flake-like thermally conductive filler 3 may be used alone or two or more types may be combined. By using a flake-like thermally conductive filler (for example, the flake-like boron nitride 3A), which are less expensive than spherical thermally conductive fillers (for example, spherical boron nitride) as the flake-like thermally conductive filler 3, both a low cost and superior thermal properties can be achieved. Also, by using a flake-like boron nitride as the flake-like thermally conductive filler 3, lower density thermally conductive sheets can be made and a load applied to an IC by the thermally conductive sheets can be further mitigated.

An average particle diameter (D50) of the flake-like thermally conductive filler 3 is not particularly limited and may be appropriately selected according to the purpose. For example, a lower limit of the average particle diameter of the flake-like thermally conductive filler can be set to 10 μm or more, and may be 20 μm or more, 30 μm or more, or 35 μm or more. Furthermore, an upper limit of the average particle size of the flake-like thermally conductive filler can be set to 150 μm or less, and may be 100 μm or less, 90 μm or less, 80 μm or less, 70 μm or less, 50 μm or less, or 45 μm or less. From the perspective of flexibility or load-dependency on a thermal resistance value of the thermally conductive sheet 1, it is preferable that the average particle size of the flake-like thermally conductive filler 3 be set to 20 to 100 μm, and more preferable that the average particle size be set to 20 to 50 μm.

An aspect ratio (average major axis/average minor axis) of the flake-like thermally conductive filler 3 is not particularly limited and may be appropriately selected according to the purpose. For example, the aspect ratio of the flake-like thermally conductive filler 3 can be set in the range of 10 to 100. The average major axis and average minor axis of the flake-like thermally conductive filler 3 can be measured by, for example, a microscope, a scanning electron microscope (SEM), a particle size distribution analyzer, or the like. As an example, when the flake-like boron nitride 3A having a hexagonal crystal shape such as illustrated in FIG. 2 is used as the flake-like thermally conductive filler 3, 200 or more of the boron nitride 3A may be arbitrarily selected from images taken by SEM, and a ratio (a/b) of respective major axes a to minor axes b may be obtained by calculating an average value.

Content of the flake-like thermally conductive filler 3 in the thermally conductive sheet 1 is not particularly limited and may be appropriately selected according to the purpose. For example, a lower limit of the content of the flake-like thermally conductive filler 3 in the thermally conductive sheet 1 can be set to 15 percent by volume or more, and may be 20 percent by volume or more or 25 percent by volume or more. Additionally, an upper limit of the content of the flake-like thermally conductive filler 3 in the thermally conductive sheet 1 can be set to 45 percent by volume or less, and may be 40 percent by volume or less, 35 percent by volume or less, or 30 percent by volume or less. From the perspective of flexibility and load-dependency on a thermal resistance value of the thermally conductive sheet 1, it is preferable that the content of the flake-like thermally conductive filler 3 in the thermally conductive sheet 1 be set to 20 to 28 percent by volume, and more preferable that the average particle size be set to 20 to 27 percent by volume. Also, from the perspective of flexibility, load-dependency on a thermal resistance value, and thermal conductivity at a low load region of the thermally conductive sheet 1, it is preferable that the content of the flake-like thermally conductive filler 3 in the thermally conductive sheet 1 be set to 21 to 27 percent by volume, and more preferable that the average particle size be set to 23 to 27 percent by volume.

<Non-Flake-Like Thermally Conductive Filler>

The non-flake-like thermally conductive filler 4 is a thermally conductive filler other than the flake-like thermally conductive filler 3 described above. A thermally conductive filler having, for example, a spherical, powder-like, granular, or flat shape can be given as an example of the non-flake-like thermally conductive filler 4. It is preferable that a material of the non-flake-like thermally conductive filler 4 be a material capable of ensuring an insulating property of the thermally conductive sheet 1; examples include: aluminum oxide (alumina, sapphire), aluminum nitride, boron nitride, zirconia, silicon carbide, and the like. One type of the non-flake-like thermally conductive filler 4 may be used alone or two or more types may be combined.

In particular, for the non-flake-like thermally conductive filler 4, from the perspective of flexibility and load-dependency on a thermal resistance value of the thermally conductive sheet 1, it is preferable that aluminum nitride particles and spherical aluminum particles be combined. From the perspective of reducing viscosity of the thermally conductive sheet 1 prior to heat curing, it is preferable that the average particle diameter (D50) of the aluminum nitride particles be set to 1 to 5 μm, and it may be 1 to 3 μm or 1 to 2 μm. In addition, from the perspective of reducing viscosity of the thermally conductive sheet 1 prior to heat curing, it is preferable that the average particle diameter (D50) of the spherical aluminum particles be set to 1 to 3 μm, and it may be 1.5 to 2.5 μm.

A total content amount of the non-flake-like thermally conductive filler 4 in the thermally conductive sheet 1 is not particularly limited and may be appropriately selected according to the purpose. A lower limit of the content of the non-flake-like thermally conductive filler 4 in the thermally conductive sheet 1 can be 10 percent by volume or more, and may be 15 percent by volume or more or 20 percent by volume or more. Additionally, an upper limit of the content of the non-flake-like thermally conductive filler 4 in the thermally conductive sheet 1 can be 50 percent by volume or less, and may be 40 percent by volume or less, 30 percent by volume or less, or 25 percent by volume or less. A total content of the non-flake-like thermally conductive filler 4 in the thermally conductive sheet 1 can be, for example, 30 to 60 percent by volume.

When spherical alumina particles are used alone as the non-flake-like thermally conductive filler 4, from the perspective of the viscosity of the thermally conductive sheet 1 prior to heat curing, it is preferable that the content of the spherical alumina particles in the thermally conductive sheet 1 be set to 10 to 45 percent by volume. Moreover, as described above, when aluminum nitride particles and spherical alumina particles are used in combination as the non-flake-like thermally conductive filler 4, from the perspective of the viscosity of the thermally conductive sheet 1 prior to heat curing, it is preferable that the content of the spherical alumina particles in the thermally conductive sheet 1 be set to 10 to 25 percent by volume, and that the total content of the aluminum nitride particles be set to 10 to 25 percent by volume.

Also, from the perspective of flexibility, load-dependency on a thermal resistance value, and thermal conductivity at a low load region of the thermally conductive sheet 1, it is preferable that a total content amount of the flake-like thermally conductive filler 3 and the non-flake-like thermally conductive filler 4 in the thermally conductive sheet 1 be less than 70 percent by volume, and more preferable that the total content amount be set to 67 percent by volume or less. Furthermore, from the perspective of flexibility, load-dependency on a thermal resistance value of the thermally conductive sheet 1, it is preferable that a lower limit of the total content amount of the flake-like thermally conductive filler 3 and the non-flake-like thermally conductive filler 4 in the thermally conductive sheet 1 be 60 percent by volume or more, and from the perspective of flexibility, load-dependency on a thermal resistance value, and thermal conductivity at a low load region of the thermally conductive sheet 1, it is preferable that the total content amount be set to 63 percent by volume or more.

The thermally conductive sheet 1 may further contain a component other than those described above as long as the effect of the present technology is not impaired. Examples of other components include: dispersants, curing accelerators, retardants, tackifiers, plasticizers, flame retardants, antioxidants, stabilizers, colorants, and the like.

As described above, the thermally conductive sheet 1 contains the curable resin composition 2, the flake-like thermally conductive filler 3, and the non-flake-like thermally conductive filler 4. Moreover, in the thermally conductive sheet 1, a difference between a thermal resistance value at a load of 1 kgf/cm² and a thermal resistance value at a load in the range of 1 kgf/cm² to 3 kgf/cm² is 0.4° C.·cm²/W or less and, for example, a compression ratio at a load of 3 kgf/cm² is 20% or more. Further, in the thermally conductive sheet 1, the difference between a compression ratio at a load of 3 kgf/cm² and a compression ratio at a load of 1 kgf/cm² is no less than 20%. Thus, the thermally conductive sheet 1 has superior flexibility and low load-dependency on thermal resistance.

In the thermally conductive sheet 1, the flake-like thermally conductive filler 3 is aligned in the thickness direction B of the thermally conductive sheet 1 (see FIG. 1). For example, in the thermally conductive sheet 1, an effective thermal conductivity in an oriented direction of the flake-like thermally conductive filler 3 (for example, the thickness direction B of the thermally conductive sheet 1) may be two times or more than effective thermal conductivity in a non-oriented direction of the flake-like thermally conductive filler 3 (for example, a surface direction A of the thermally conductive sheet 1).

An average thickness of the thermally conductive sheet 1 is not particularly limited and may be appropriately selected according to the purpose. For example, a lower limit of the average thickness of a thermally conductive sheet can be set to 0.05 mm or more and can also be set to 0.1 mm or more. In addition, an upper limit of the average thickness of the thermally conductive sheet can be set to 5 mm or less, or may be 4 mm or less or 3 mm or less. From the perspective of handling properties of the thermally conductive sheet 1, it is preferable that an average thickness of the thermally conductive sheet 1 be set to 0.1 to 4 mm, and the average thickness can be set to 0.5 to 3 mm. The average thickness of the thermally conductive sheet 1 can be obtained, for example, by measuring a thickness of the thermally conductive sheet at any five locations and taking an arithmetic average value therefrom.

<Method for Manufacturing a Thermally Conductive Sheet>

A method for manufacturing a thermally conductive sheet according to the present technique includes, for example, the steps A, B, and C described hereinafter.

<Step A>

In step A, a composition for forming a thermally conductive sheet is prepared by dispersing the flake-like thermally conductive filler 3 and the non-flake-like thermally conductive filler 4 into the curable resin composition 2. The composition for forming a thermally conductive sheet can be prepared by uniformly mixing the flake-like thermally conductive filler 3, the non-flake-like thermally conductive filler 4, and the curable resin composition 2, as well as a given type of additive or volatile solvent as necessary by a known procedure.

<Step B>

In step B, a molded body block is formed from the prepared composition for forming a thermally conductive sheet. Examples of methods for forming the molded body block include: extrusion molding, die molding, and the like. The extrusion molding method and the die molding method are not particularly limited, and can be appropriately adopted from among various types of known extrusion molding methods and die molding methods according to a viscosity of the composition for forming a thermally conductive sheet, characteristics required for the thermally conductive sheet, and the like.

For example, with an extrusion molding method, when the composition for forming a thermally conductive sheet is extruded from a die, or in a die molding method, when the composition for forming a thermally conductive sheet is press fitted into a mold, a binder resin flows and the flake-like thermally conductive filler 3 aligns along a direction of flow.

A size and shape of the molded body block can be determined according to a size of a thermally conductive sheet 1 to be obtained. A rectangular parallelepiped having a longitudinal cross-section of 0.5 to 15 cm and a lateral cross-section of 0.5 to cm can be given as an example. A length of the rectangular parallelepiped may be determined as necessary. With an extrusion molding method, it is easy to form a columnar molded body block composed of a cured product of the resin composition for forming a thermally conductive sheet, having the flake-like thermally conductive filler 3 oriented in the direction of extrusion.

<Step C>

In step C, the molded body block is sliced into sheets to obtain the thermally conductive sheet 1. The flake-like thermally conductive filler 3 is exposed to a surface of the sheet obtained by slicing (slice surface). A method for slicing is not particularly limited and can be selected from among known slicing devices (preferably an ultrasonic cutter) according to a size or mechanical strength of the molded body block. As for a slicing direction of the molded body block, when the molding method is an extrusion molding method, since an alignment may be in an extrusion direction, it is preferable that the direction be 60 to 120 degrees with respect to the extrusion direction, more preferable that the direction be 70 to 100 degrees, and even more preferable that the direction be 90 degrees (perpendicular). When the columnar molded body block is formed by extrusion molding in step B, it is preferable that the slicing be done in a direction substantially orthogonal to the length direction of the molded body block.

In this manner, the thermally conductive sheet 1 described above can be obtained according to the method for manufacturing a thermally conductive sheet, which has steps A, B, and C.

The method for manufacturing a thermally conductive sheet according to the present technology is not limited to the example described above, and may further include, for example, a step D for pressing a slice surface following step C. By including step D for pressing in the method for manufacturing a thermally conductive sheet, a surface of the sheet obtained in step C can be made smoother, which may further improve close adhesion to another material. A pair of pressing instruments composed of a flat plate and a press head having a flat surface can be used as a method for pressing. Furthermore, pressing may be performed by pinch rolling. A pressure while pressing can be set, for example, to 0.1 to 100 MPa. In order to make pressing more effective and shorten a pressing time, it is preferable that pressing be performed at a glass transition temperature (Tg) of the curable resin composition 2 or hotter. For example, a pressing temperature can be set to 0 to 180° C., and may be within the temperature range from room temperature (for example, 25° C.) to 100° C., or may be 30 to 100° C.

<Electronic Equipment>

The thermally conductive sheet according to the present technology can be, for example, disposed between a heat generating body and a heat dissipating body—arranged therebetween to allow heat generated by the heat generating body to escape to the heat dissipating body—forming an electronic device (thermal device). The electronic device has at least the heat generating body, the heat dissipating body, and the thermally conductive sheet, and may further have another member as necessary.

The heat generating body is not particularly limited, and examples include: a CPU, GPU (graphics processing unit), DRAM (dynamic random access memory), flash memory, or another integrated circuit element, a transistor, resistor, or other electronic equipment that dissipates heat in an electric circuit. Moreover, the heat generating body may also include equipment for receiving an optical signal such as an optical transceiver in a communication device.

The heat dissipating body is not particularly limited and examples include: a heat sink, heat spreader, and the like, which are used in combination with integrated circuit elements, or transistors, optical transceiver housings, and the like. In addition to heat spreaders or heat sinks, the heat dissipating body may be a unit that conducts heat generated by a heat source to the outside and dissipates the heat, examples include: a radiator, cooler, die pad, printed circuit board, cooling fan, Peltier element, heat pipe, metal cover, housing, and the like.

FIG. 3 is a cross-sectional view illustrating an example of a semiconductor device 50 to which the thermally conductive sheet 1 according to the present technology is applied. For example, as illustrated in FIG. 3, the thermally conductive sheet 1 is mounted on the semiconductor device 50, which is built-in to various electronic devices, and is interposed between a heat generating body and a heat dissipating body. The semiconductor device 50 illustrated in FIG. 3 is provided with an electronic component 51, a heat spreader 52, and the thermally conductive sheet 1, and the thermally conductive sheet 1 is interposed between the heat spreader 52 and the electronic component 51. By interposing the thermally conductive sheet 1 between the heat spreader 52 and a heat sink 53, a heat dissipating member that dissipates heat of the electronic component 51 is configured together with the heat spreader 52. A mounting location of the thermally conductive sheet 1 is not limited to being between the heat spreader 52 and the electronic equipment 51 or between the heat spreader 52 and the heat sink 53, and can be appropriately selected according to the configuration of an electronic device or semiconductor device.

### EXAMPLES

Examples of the present technology are described below. In these Examples, a thermally conductive sheet is fabricated and changes in a compression ratio and a thermal resistance value of the thermally conductive sheet, changes in the compression ratio, and an effective thermal conductivity are measured. Note that the present technology is not limited to these Examples.

### Example 1

A resin composition for forming a thermally conductive sheet was prepared by uniformly mixing 33 percent by volume of a silicone resin, 27 percent by volume of a flake-like boron nitride (D50 being 40 μm) having a hexagonal crystal shape, 20 percent by volume of an aluminum nitride (D50 being 1.2 μm), and 20 percent by volume of spherical alumina particles (D50 being 2 μm). The resin composition for forming the thermally conductive sheets was poured into a die (opening: 50 mm×50 mm) having a rectangular parallelepiped inner space and heated in a 60° C. oven for four hours to form a molded body block. Note that a removable polyethylene terephthalate film was attached to an inner surface of the die so that a peel processed surface formed an inner side. The resulting molded body block was sliced into 0.5 mm thick, 1 mm thick, 2 mm thick, and 3 mm thick sheets by an ultrasonic cutter to obtain thermally conductive sheets in which the flake-like boron nitride was aligned in a thickness direction of the sheets.

### Example 2

A resin composition for forming a thermally conductive sheet was prepared by uniformly mixing 37 percent by volume of a silicone resin, 23 percent by volume of a flake-like boron nitride (D50 being 40 μm) having a hexagonal crystal shape, 20 percent by volume of an aluminum nitride (D50 being 1.2 μm), and 20 percent by volume of spherical alumina particles (D50 being 2 μm), otherwise, the thermally conductive sheets were obtained by the same method as in Example 1.

### Example 3

A resin composition for forming a thermally conductive sheet was prepared by uniformly mixing 40 percent by volume of a silicone resin, 20 percent by volume of a flake-like boron nitride (D50 being 40 μm) having a hexagonal crystal shape, 20 percent by volume of an aluminum nitride (D50 being 1.2 μm), and 20 percent by volume of spherical alumina particles (D50 being 2 μm), otherwise, the thermally conductive sheets were obtained by the same method as in Example 1.

### Comparative Example 1

A resin composition for forming a thermally conductive sheet was prepared by uniformly mixing 31 percent by volume of a silicone resin, 29 percent by volume of a flake-like boron nitride (D50 being 40 μm) having a hexagonal crystal shape, 20 percent by volume of an aluminum nitride (D50 being 1.2 μm), and 20 percent by volume of spherical alumina particles (D50 being 2 μm), otherwise, the thermally conductive sheets were obtained by the same method as in Example 1.

### Comparative Example 2

A resin composition for forming a thermally conductive sheet was prepared by uniformly mixing 28 percent by volume of a silicone resin, 32 percent by volume of a flake-like boron nitride (D50 being 40 μm) having a hexagonal crystal shape, 20 percent by volume of an aluminum nitride (D50 being 1.2 μm), and 20 percent by volume of spherical alumina particles (D50 being 2 μm), otherwise being performed similarly to Example 1.

<Compression Ratio>

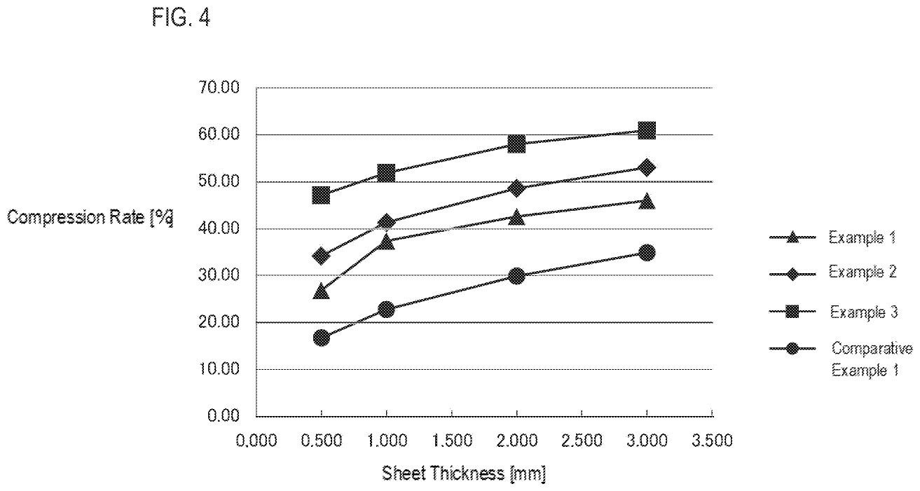

By measuring a thickness of the thermally conductive sheets after a load of 3 kgf/cm² was applied to the thermally conductive sheets obtained in the respective Examples and Comparative Examples and stabilized, compression ratios (%) of the thermally conductive sheets were calculated from thicknesses of the thermally conductive sheets before and after the load was applied. The results are illustrated in Table 1 and FIG. 4. FIG. 4 is a graph illustrating a relationship between thicknesses and compression ratios of the thermally conductive sheets. In FIG. 4, the horizontal axis represents the thicknesses (mm) of the thermally conductive sheets, and the vertical axis represents the compression ratios (%). In FIG. 4, the results of the thermally conductive sheets for Example 1, Example 2, Example 3, and Comparative Example 1 are respectively represented by: ▴, ♦, ▪, and •.

Furthermore, from the results in Table 1 and FIG. 4, the compression ratio of the thermally conductive sheets of Examples 1 to 3 at a load of 3 kgf/cm² was found to be 20% or more for the range of thicknesses 0.5 to 3 mm.

<Change in Thermal Resistance Value>

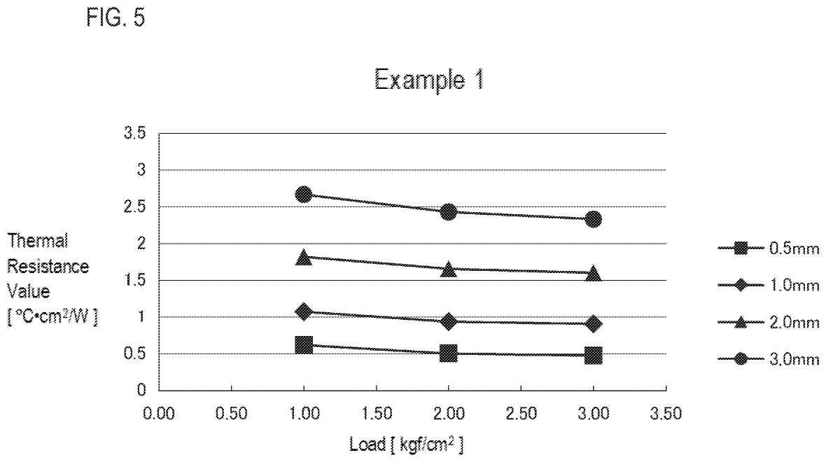

The thermal resistance value (° C.·cm²/W) of the thermally conductive sheets was obtained as follows. Thermal resistance was measured in a state in which a thermally conductive sheet having a uniform thickness was interposed between a heat source and a heat dissipating member and a predetermined load (1 kgf/cm², 2 kgf/cm², and 3 kgf/cm²) was applied. From the obtained measurement results, the difference between the thermal resistance value at a load of 1 kgf/cm² and the thermal resistance value at a load in the range of 1 kgf/cm² to 3 kgf/cm² (2 kgf/cm² or 3 kgf/cm²) was obtained. The results are illustrated in Table 1 and FIGS. 5 to 8.

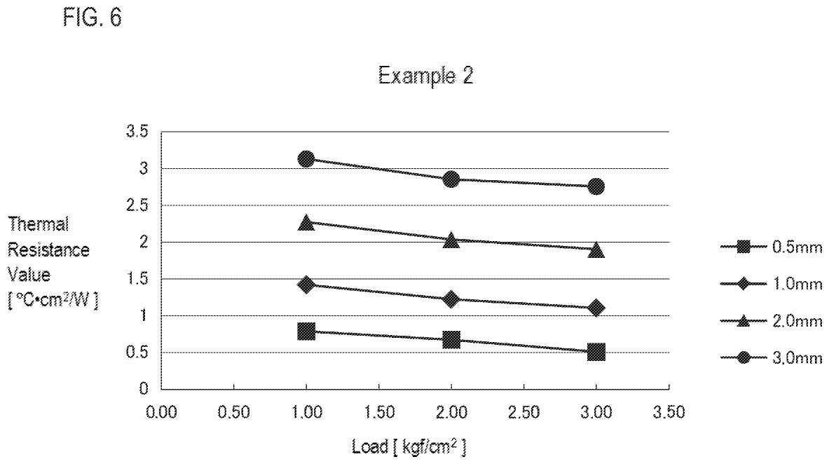

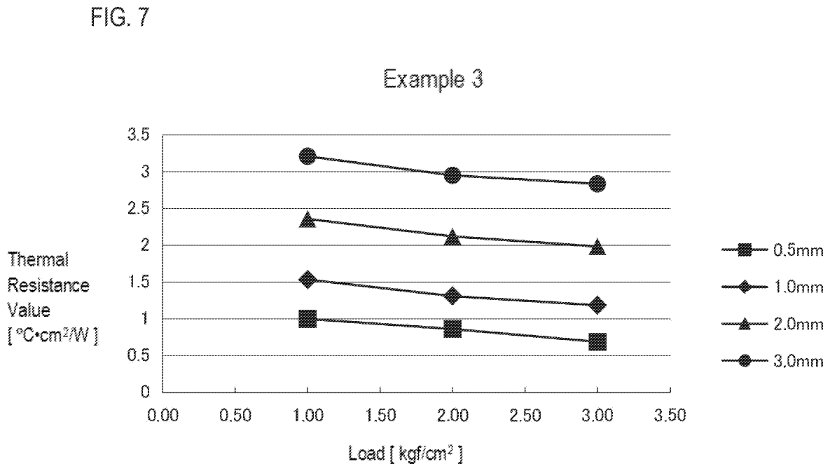

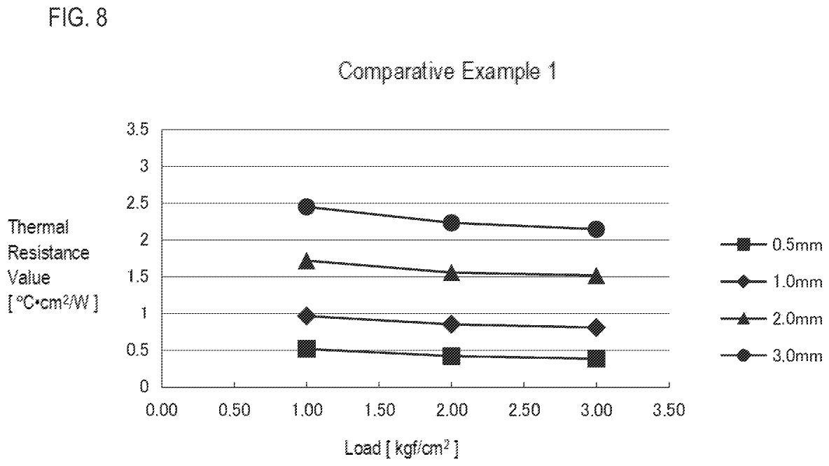

In FIGS. 5 to 8, the horizontal axis represents the load (kgf/cm²), and the vertical axis represents the thermal resistance value (° C.·cm²/W). FIG. 5 is a graph illustrating a relationship between loads and thermal resistance values for the thermally conductive sheet in Example 1. FIG. 6 is a graph illustrating a relationship between loads and thermal resistance values for the thermally conductive sheet in example 2. FIG. 7 is a graph illustrating a relationship between loads and thermal resistance values for the thermally conductive sheet in example 3. FIG. 8 is a graph illustrating a relationship between loads and thermal resistance values for the thermally conductive sheet in comparative Example 1. In FIGS. 5 to 8, for the results of the thermally conductive sheets, ▪ represents a thickness of 0.5 mm, ♦ represents a thickness of 1.0 mm, ▴ represents a thickness of 2.0 mm, and • represents a thickness of 3.0 mm. The numerical values for the difference of the thermal resistance values in Table 1 represent the difference between the thermal resistance values at a load of 1 kgf/cm² and a load of 3 kgf/cm².

From the results in Table 1 and FIGS. 5 to 8, the difference for the thermally conductive sheets of Examples 1 to 3 between a thermal resistance value at a load of 1 kgf/cm² and a thermal resistance value at a load in the range of 1 kgf/cm² to 3 kgf/cm² (a load of 2 kgf/cm² or a load of 3 kgf/cm²) was found to be 0.4° C.·cm²/W or less for the range of thicknesses 0.5 to 3 mm.

<Change in Compression Ratio>

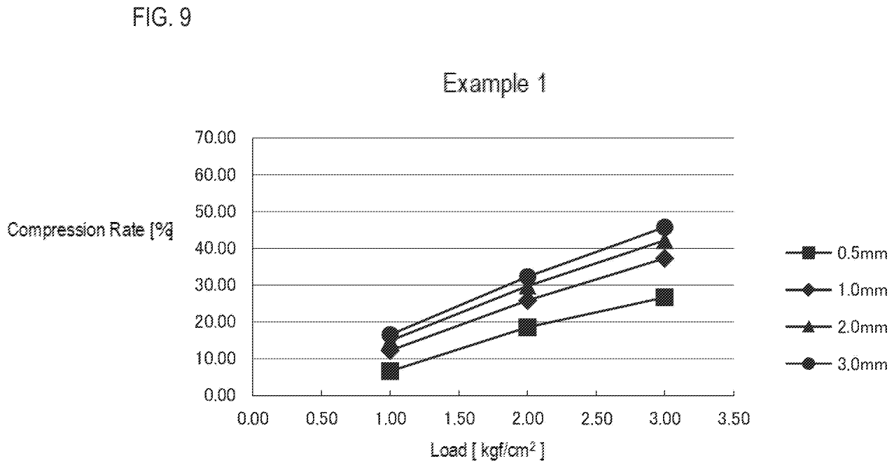

The change (%) in the compression ratio of the thermally conductive sheet is obtained as follows. The initial thicknesses (0.5 mm, 1 mm, 2 mm or 3 mm) of the thermally conductive sheet were set to 100%, and the compression ratio of the thermally conductive sheet when a predetermined load (1 kgf/cm², 2 kgf/cm², or 3 kgf/cm²) was applied was measured. The difference between the compression ratio at a load of 3 kgf/cm² and the compression ratio at a load of 1 kgf/cm² was calculated from the obtained measurement results. The results are illustrated in Table 1 and FIGS. 9 to 12.

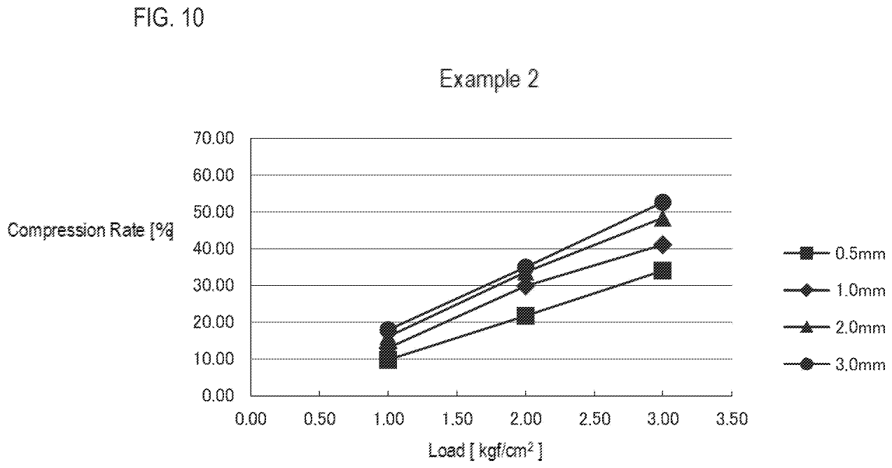

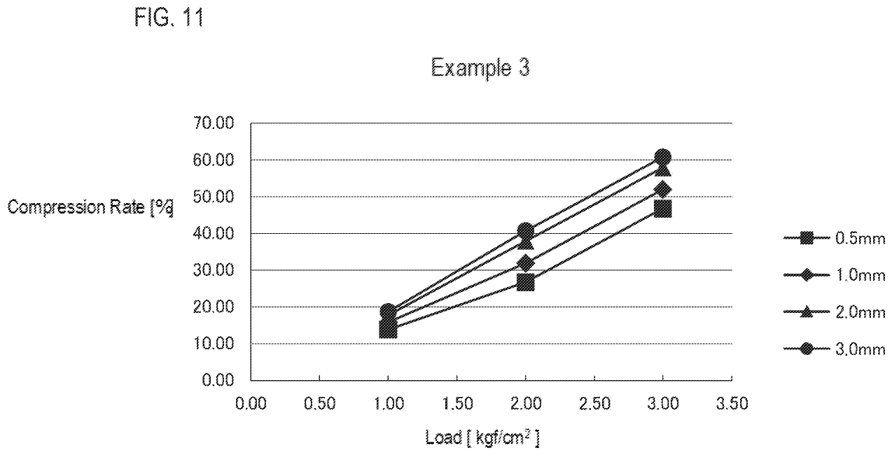

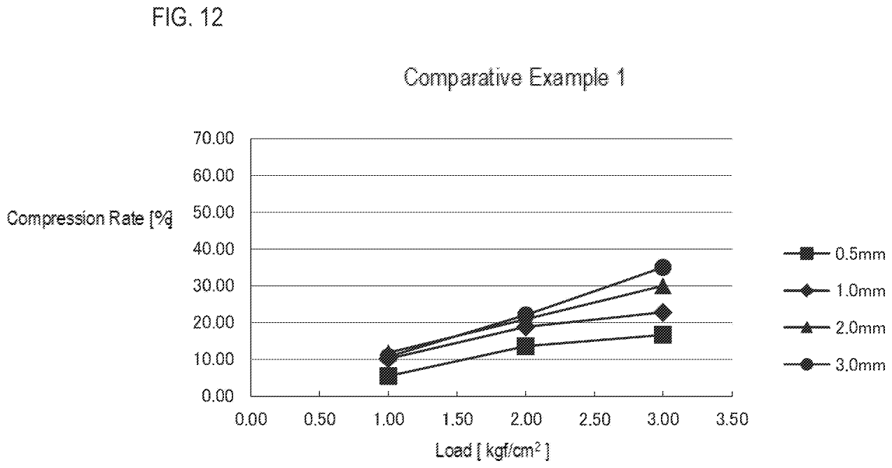

In FIGS. 9 to 12, the horizontal axis represents the load (kgf/cm²), and the vertical axis represents the compression ratio (%). FIG. 9 is a graph illustrating a relationship between loads and compression ratios for the thermally conductive sheets in Example 1. FIG. 10 is a graph illustrating a relationship between loads and compression ratios for the thermally conductive sheets in Example 2. FIG. 11 is a graph illustrating a relationship between loads and compression ratios for the thermally conductive sheets in Example 3. FIG. 12 is a graph illustrating a relationship between loads and compression ratios for the thermally conductive sheets in Comparative Example 1. In FIGS. 9 to 12, for the results of the thermally conductive sheets, ▪ represents a thickness of 0.5 mm, ♦ represents a thickness of 1.0 mm, ▴ represents a thickness of 2.0 mm, and • represents a thickness of 3.0 mm. The numerical values for the difference of the compression ratio in Table 1 represent the difference between the compression ratios at a load of 3 kgf/cm² and a load of 1 kgf/cm².

Furthermore, from the results in Table 1 and FIGS. 9 to 12, the difference between the compression ratios of the thermally conductive sheets of Examples 1 to 3 at a load of 3 kgf/cm² and the compression ratios at a load of 1 kgf/cm² was found to be 20% or more for the range of thicknesses 0.5 to 3 mm.

<Effective Thermal Conductivity>

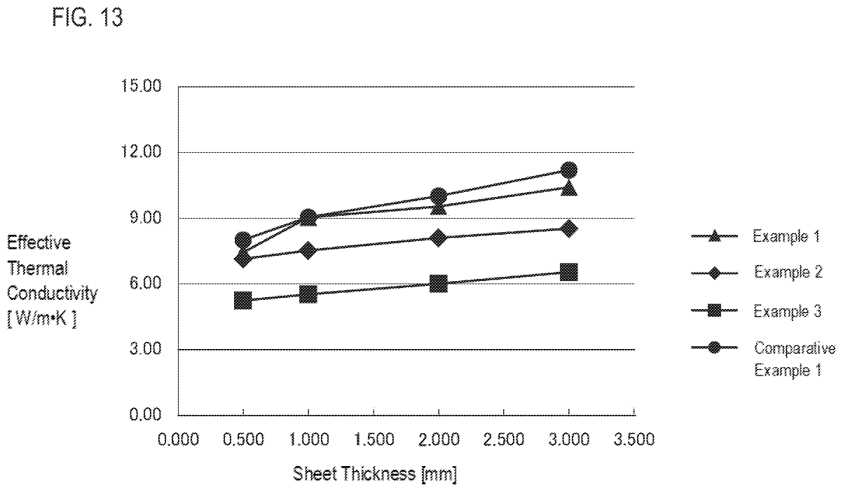

The effective thermal conductivity (W/m·K) of the thermally conductive sheets was measured using a thermal resistance measurement device in accordance with ASTM-D5470 at a load of 1 kgf/cm². The results are illustrated in Table 1 and FIG. 13. FIG. 13 is a graph illustrating a relationship between thicknesses and effective thermal conductivities of the thermally conductive sheets. In FIG. 13, the results of the thermally conductive sheets for Example 1, Example 2, Example 3, and Comparative Example 1 are respectively represented by: ▴, ♦, ▪, and •.

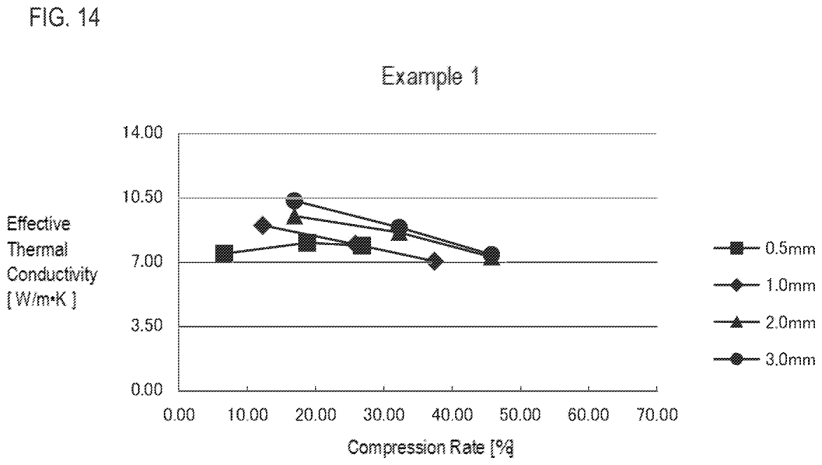

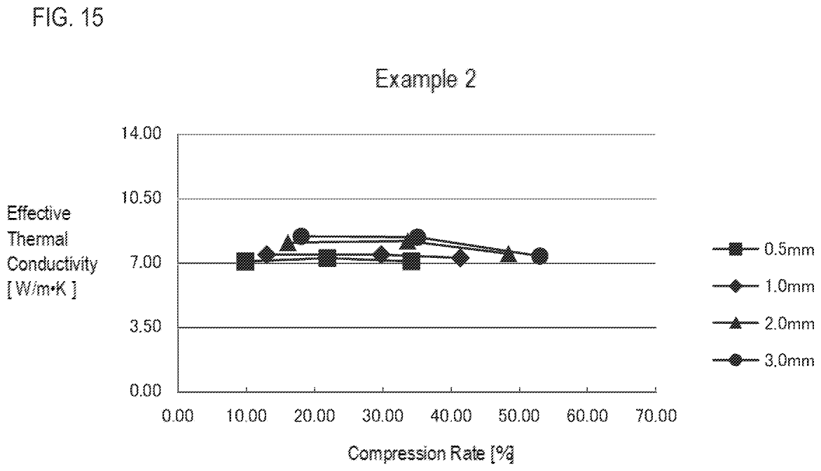

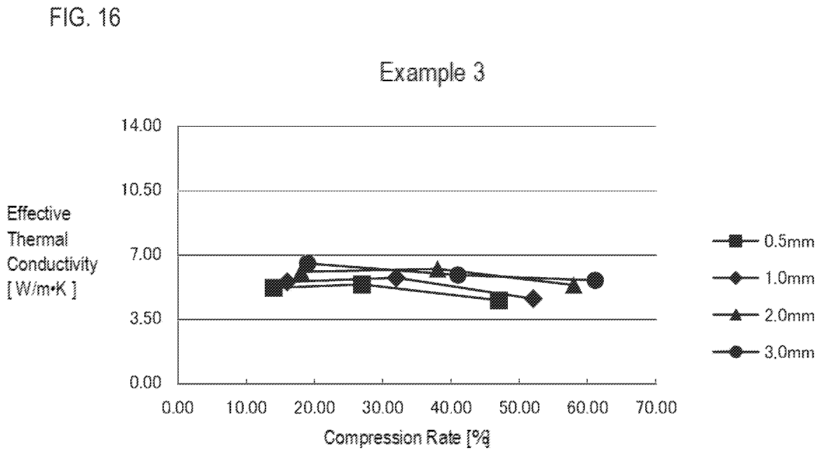

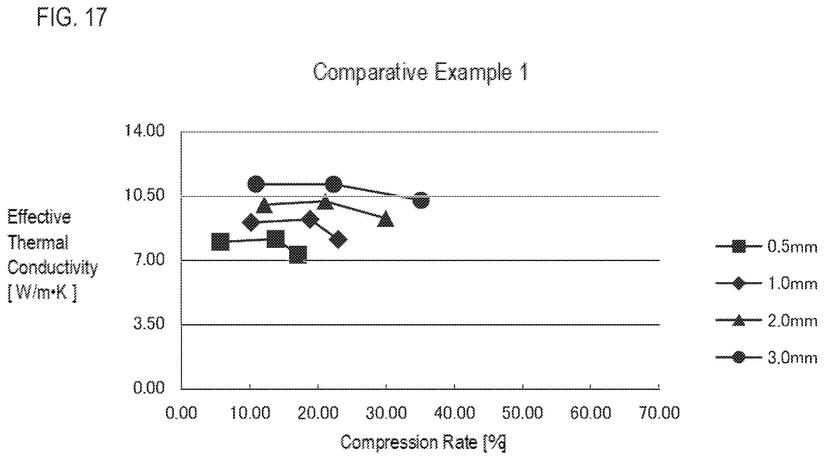

FIGS. 14 to 17 are graphs illustrating a relationship between compression ratios and effective thermal conductivities for the thermally conductive sheets. FIG. 14 is a graph illustrating a relationship between compression ratios and effective thermal conductivities for the thermally conductive sheets in Example 1. FIG. 15 is a graph illustrating a relationship between compression ratios and effective thermal conductivities for the thermally conductive sheets in Example 2. FIG. 16 is a graph illustrating a relationship between compression ratios and effective thermal conductivities for the thermally conductive sheets in Example 3. FIG. 17 is a graph illustrating a relationship between compression ratios and effective thermal conductivities for the thermally conductive sheets in Comparative Example 1. In FIGS. 14 to 17, for the results of the thermally conductive sheets, ▪ represents a thickness of mm, ♦ represents a thickness of 1.0 mm, ▴ represents a thickness of 2.0 mm, and • represents a thickness of 3.0 mm.

From the results in Table 1 and FIGS. 13 to 17, the thermally conductive sheets of Examples 1 and 2 were found to have peak values of effective thermal conductivity of 7 W/m·K or more in the range in which the compression ratio is 5 to 35%. In particular, the thermally conductive sheets of Example 1 were found to have peak values of effective thermal conductivity of 7 W/m·K or more in the range in which the compression ratio is 15 to 25% for the thicknesses 0.5 to 3 mm. In addition, the thermally conductive sheets of Example 2 were found to have peak values of effective thermal conductivity of 7 W/m·K or more in the range in which the compression ratio 15 to 25% for the thicknesses 0.5 mm, 1 mm, and 3 mm.

<Evaluation and Judgment>

Evaluation and judgment of the thermally conductive sheets of the Examples and Comparative Examples were performed based on the following criteria.

A: Cases where (i) to (iii) described below are satisfied
(i) The difference between the thermal resistance value at a load of 1 kgf/cm² and the thermal resistance value at a load in the range of 1 kgf/cm² to 3 kgf/cm² is 2/W or less
(ii) The difference between the compression ratio at a load of 3 kgf/cm² and the compression ratio at a load of 1 kgf/cm² is 20% or more
(iii) The peak value of effective thermal conductivity is 7 W/m·K or more at a compression ratio in the range of 5 to 35%.

B: Cases where only (iii) of (i) to (iii) described above is not satisfied

C: Cases other than A or B described above

TABLE 1

| | | Example 1 | | | | Example 2 | | | | Example 3 | |
|---|---|---|---|---|---|---|---|---|---|---|---|
| Thermally Conductive Sheet Thickness | | 0.5 | 1.0 | 2.0 | 3.0 | 0.5 | 1.0 | 2.0 | 3.0 | 0.5 | 1.0 |
| (mm) | | | | | | | | | | | |
| Curable | Silicon resin | 33 | | | | 37 | | | | 40 | |
| Resin | filling ratio by | | | | | | | | | | |
| Composition | volume (vol %) | | | | | | | | | | |
| Flake-Like | Flake-like boron nitride | 27 | | | | 23 | | | | 20 | |
| Thermally | (D50 = 40 μm) | | | | | | | | | | |
| Conductive | filling ratio by | | | | | | | | | | |
| Filler | volume (vol %) | | | | | | | | | | |
| Non-Flake- | Aluminum nitride | 20 | | | | 20 | | | | 20 | |
| Like | (D50 = 1.2 μm) | | | | | | | | | | |
| Thermally | filling ratio by | | | | | | | | | | |
| Conductive | volume (vol %) | | | | | | | | | | |
| Filler | Spherical alumina | 20 | | | | 20 | | | | 20 | |
| | (D50 = 2 μm) | | | | | | | | | | |
| | filling ratio by | | | | | | | | | | |
| | volume (vol %) | | | | | | | | | | |
| Thermally | Compression ratio (%) | 27 | 37 | 42 | 46 | 30 | 41 | 48 | 53 | 47 | 52 |
| Conductive | @ 3 kgf/cm² | | | | | | | | | | |
| Sheet | Difference in thermal | 0.14 | 0.16 | 0.21 | 0.32 | 0.27 | 0.31 | 0.37 | 0.39 | 0.31 | 0.34 |
| Evaluation | resistance values | | | | | | | | | | |
| | (° C. · cm²/W) | | | | | | | | | | |
| | 1 kgf/cm² → 3 kgf/cm² | | | | | | | | | | |
| | Difference in | 20 | 25 | 27 | 29 | 24 | 28 | 32 | 35 | 33 | 36 |
| | compression ratios (%) | | | | | | | | | | |
| | 1 kgf/cm² → 3 kgf/cm² | | | | | | | | | | |
| | Effective thermal | 7.5 | 9 | 9.5 | 10 | 7.1 | 7.5 | 8 | 8.5 | 5 | 5.5 |
| | conductivity (W/m · K) | | | | | | | | | | |
| | @ 1 kgf/cm² | | | | | | | | | | |

| | | | | |
|---|---|---|---|---|
| Evaluation and judgment | A | A | B | C |

| | Example 3 | | Comparative Example 1 | | | | Comparative Example 2 | | | |
|---|---|---|---|---|---|---|---|---|---|---|
| Thermally Conductive Sheet Thickness | 2.0 | 3.0 | 0.5 | 1.0 | 2.0 | 3.0 | 0.5 | 1.0 | 2.0 | 3.0 |
| (mm) | | | | | | | | | | |

| | | | | |
|---|---|---|---|---|
| Curable | Silicon resin | 40 | 31 | 28 |
| Resin | filling ratio by | | | |
| Composition | volume (vol %) | | | |
| Flake-Like | Flake-like boron nitride | 20 | 29 | 32 |
| Thermally | (D50 = 40 μm) | | | |
| Conductive | filling ratio by | | | |
| Filler | volume (vol %) | | | |
| Non-Flake- | Aluminum nitride | 20 | 20 | 20 |
| Like | (D50 = 1.2 μm) | | | |
| Thermally | filling ratio by | | | |
| Conductive | volume (vol %) | | | |
| Filler | Spherical alumina | 20 | 20 | 20 |
| | (D50 = 2 μm) | | | |
| | filling ratio by | | | |
| | volume (vol %) | | | |

| | | | | | | | | | | | |
|---|---|---|---|---|---|---|---|---|---|---|---|
| Thermally | Compression ratio (%) | 58 | 61 | 17 | 23 | 30 | 35 | — | — | — | — |
| Conductive | @ 3 kgf/cm² | | | | | | | | | | |
| Sheet | Difference in thermal | 0.36 | 0.38 | 0.13 | 0.15 | 0.20 | 0.31 | — | — | — | — |
| Evaluation | resistance values | | | | | | | | | | |
| | (° C. · cm²/W) | | | | | | | | | | |
| | 1 kgf/cm² → 3 kgf/cm² | | | | | | | | | | |
| | Difference in | 40 | 42 | 11 | 13 | 18 | 24 | — | — | — | — |
| | compression ratios (%) | | | | | | | | | | |
| | 1 kgf/cm² → 3 kgf/cm² | | | | | | | | | | |
| | Effective thermal | 6 | 6.5 | 8 | 9 | 10 | 11 | — | — | — | — |
| | conductivity (W/m · K) | | | | | | | | | | |
| | @ 1 kgf/cm² | | | | | | | | | | |

| | | |
|---|---|---|
| Evaluation and judgment | C | C (unable to measure) |

From the above results, the thermally conductive sheets of Examples 1 to 3 have a curable resin composition and contain a flake-like thermally conductive filler and a non-flake-like thermally conductive filler, and were found to have the difference between a thermal resistance value at a load of 1 kgf/cm² and a thermal resistance value at a load in the range of 1 kgf/cm² to 3 kgf/cm² of 0.4° C.·cm²/W or less, and the difference between a compression ratio at a load of 3 kgf/cm² and a compression ratio at a load of 1 kgf/cm² of 20% or more. That is, it was found that the thermally conductive sheets of Examples 1 to 3 have superior flexibility and low load-dependency on thermal resistance.

In particular, the thermally conductive sheets of Examples 1 and 2 were found to have peak values of effective thermal conductivity of 7 W/m·K or more in the range in which the compression ratio is 5 to 35%. That is, in addition to having superior flexibility and low load-dependency on thermal resistance, the thermally conductive sheets of Examples 1 and 2 were found to have a peak value of conductivity in a low load region.

The difference between the compression ratio of the thermally conductive sheet of Comparative Example 1 at a load of 3 kgf/cm² and the compression ratio at a load of 1 kgf/cm² was found to be less than 20% for thicknesses 0.5 to 2 mm. That is, the thermally conductive sheets of Comparative Example 1 were found to have unfavorable flexibility.

In Comparative Example 2, due to difficulties in forming the thermally conductive sheets, each of the evaluations described above were not able to be performed. This is thought to be due to the amount of thermally conductive filler being excessive for the curable resin composition.

### REFERENCE SIGNS LIST

1 Thermally conductive sheet, 2 Curable resin composition, 3 Flake-like thermally conductive filler 3A, Flake-like boron nitride, 4 Non-flake-like thermally conductive filler, 50 Semiconductor device, 51 Electronic equipment, 52 Heat spreader, 53 Heat sink

1. A thermally conductive sheet, comprising:
a curable resin composition;
a flake-like thermally conductive filler; and
a non-flake-like thermally conductive filler,
wherein a difference between a thermal resistance value at a load of 1 kgf/cm² and a thermal resistance value at a load of 3 kgf/cm² is 0.4° C.·cm²/W or less, and
a difference between a compression ratio at a load of 3 kgf/cm² and a compression ratio at a load of 1 kgf/cm² is 20% or more.

2. The thermally conductive sheet according to claim 1, wherein the curable resin composition is a liquid silicon resin formed by subjecting two liquids, which are a silicone primary agent and a curing agent, to an addition reaction,
the mass ratio of the silicone primary agent and the curing agent (silicone primary agent:curing agent) being from 5:5 to 7:3.

3. The thermally conductive sheet according to claim 1, wherein an average particle diameter (D50) of the flake-like thermally conductive filler is from 20 to 50 μm.

4. The thermally conductive sheets according to claim 1, wherein a peak value of effective thermal conductivity is 7 W/m·K or more in a range in which the compression ratio is from 5 to 35%.

5. The thermally conductive sheet according to claim 1, wherein a total content of the flake-like thermally conductive filler and the non-flake-like thermally conductive filler in the thermally conductive sheet is less than 70 percent by volume relative to a total volume of the thermally conductive sheet.

6. The thermally conductive sheet according to claim 1, wherein a thickness of the thermally conductive sheet is from 0.5 to 3 mm.

7. The thermally conductive sheet according to claim 1, wherein the compression ratio at a load of 3 kgf/cm² is 20% or more.

8. A method for manufacturing a thermally conductive sheet, comprising:
dispersing a flake-like thermally conductive filler and a non-flake-like thermally conductive filler in a curable resin composition to obtain a resin composition;
forming a molded body block from the resin composition; and
slicing the molded body block into sheets to obtain the thermally conductive sheet,
wherein a difference between a thermal resistance value at a load of 1 kgf/cm² and a thermal resistance value at a load of 3 kgf/cm² is 0.4° C.·cm²/W or less, and a difference between a compression ratio at a load of 3 kgf/cm² and a compression ratio at a load of 1 kgf/cm² is 20% or more.

9. The method according to claim 8, wherein the molded body block is formed by an extrusion molding method or a die molding method from the resin composition.

10. The method according to claim 8, wherein the molded body block is composed of a cured product of the resin composition having a columnar shape, and is formed by an extrusion molding method, and the thermally conductive sheet is obtained by slicing the molded body block in a direction substantially orthogonal to a length direction of the molded body block.

11. An electronic device, comprising:
a heat generating body;
a heat dissipating body; and
the thermally conductive sheet according to claim 1 disposed between the heat generating body and the heat dissipating body.
